(19) United States
(12) Patent Application Publication
(10) Pub. No.: US 2026/0314041 A1
(43) Pub. Date: Oct. 8, 2026

(54) CPODE LANDING STRUCTURE ON INSULATOR SUBSTRATE AND THE METHODS OF FORMING THE SAME

(71) Applicant: Taiwan Semiconductor Manufacturing Co., Ltd., Hsinchu (TW)

(72) Inventors: Ming-Heng Tsai, Taipei (TW); Ta-Chun Lin, Hsinchu (TW)

(21) Appl. No.: 19/714,958

(22) Filed: Jun. 22, 2026

Related U.S. Application Data
(63) Continuation of application No. 18/807,091, filed on Aug. 16, 2024.

(51) Int. Cl. H10D 84/83; H10D 30/01; H10D 30/43; H10D 30/67; H10D 62/10; H10D 64/01; H10D 84/01; H10D 84/03; H10P 14/60; H10W 10/00; H10W 10/17

(52) U.S. Cl. CPC H10D 84/83; H10D 64/017; H10D 84/0151; H10D 84/038; H10P 14/60; H10W 10/0145; H10W 10/17; H10D 30/014; H10D 30/43; H10D 30/6735; H10D 30/6757; H10D 62/121

(57) ABSTRACT

A method includes forming a dummy gate stack on a first protruding structure of a wafer, wherein the first protruding structure comprises a first semiconductor layer, etching the dummy gate stack to form a trench in the dummy gate stack and to reveal the first semiconductor layer, and removing the first semiconductor layer and a semiconductor strip underlying the first semiconductor layer to extend the trench downwardly. The trench is filled with a dielectric material to form a dielectric isolation region. A backside grinding process is performed on a semiconductor substrate of the wafer. The dielectric isolation region is revealed from a backside of the wafer. A backside dielectric layer is formed. on the backside of the wafer, and the backside dielectric layer contacts the dielectric isolation region.

### PRIORITY CLAIM AND CROSS-REFERENCE

This application is a continuation of U.S. patent application Ser. No. 18/807,091, filed Aug. 16, 2024, and entitled “CPODE LANDING STRUCTURE ON INSULATOR SUBSTRATE AND THE METHODS OF FORMING THE SAME,” which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 20A and 20B illustrate the views of intermediate stages in the formation of transistors and a Continuous Polysilicon on Diffusion Edge (CPODE) isolation region in accordance with some embodiments.

FIGS. 21 and 22 illustrate the views of intermediate stages in the formation of transistors and a CPODE isolation region in accordance with alternative embodiments.

FIGS. 23 and 24 illustrate the views of intermediate stages in the formation of transistors and a CPODE isolation region in accordance with yet alternative embodiments.

FIG. 25 illustrates a leakage path that may be formed in a structure that does not have the CPODE isolation region in accordance with some embodiments.

FIG. 26 illustrates a process flow for forming a nanostructure transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Continuous Polysilicon on Diffusion Edge (CPODE) isolation region (which is a dielectric isolation region) and the method of forming the same are provided. In accordance with some embodiments of the present disclosure, a single-layer CPODE isolation region is formed. The single-layer CPODE isolation region may be free from oxide liner. In accordance with some embodiments in which the sacrificial layers between nanostructures of Gate-All-Around (GAA) transistors are formed of an oxide, if the CPODE isolation region includes an oxide liner, the oxide liner may be damaged when the sacrificial layers are removed, causing leakage issues. In accordance with the embodiments of the present disclosure, the CPODE isolation region is formed using a dielectric material(s) different from the material of the sacrificial layers.

Although GAA transistors are discussed to explain the concept of the present disclosure, the embodiments may be applied to other types of transistors including, and not limited to, planar transistors, Fin Field-Effect Transistors (FinFETs), Complementary Field-Effect Transistors (CFETs), and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

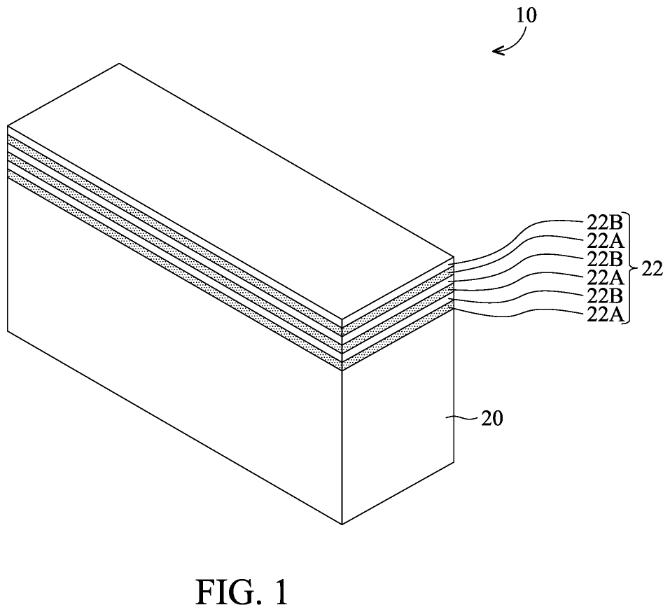

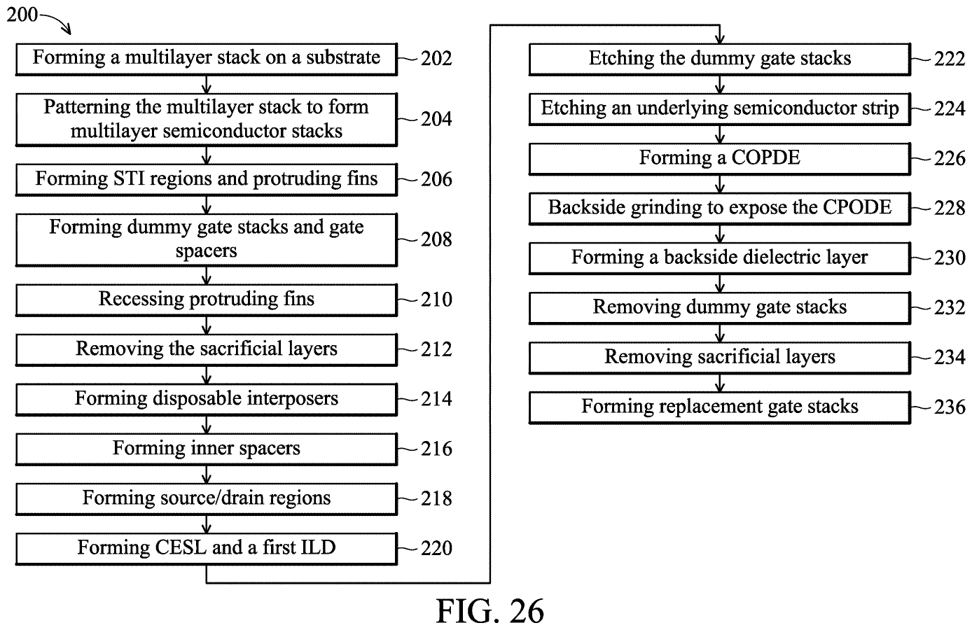

FIGS. 1 through 20A and 20B illustrate the cross-sectional views of intermediate stages in the formation of GAA transistors and a CPODE isolation region in accordance with some embodiments of the present disclosure. The corresponding processes are also reflected schematically in the process flow shown in FIG. 26.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 26. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises a semiconductor such as SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the first layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

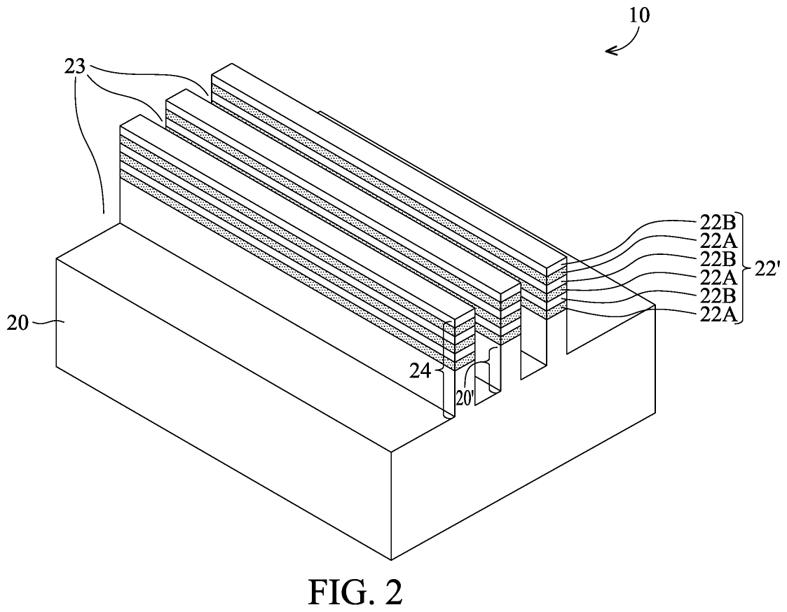

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 26. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

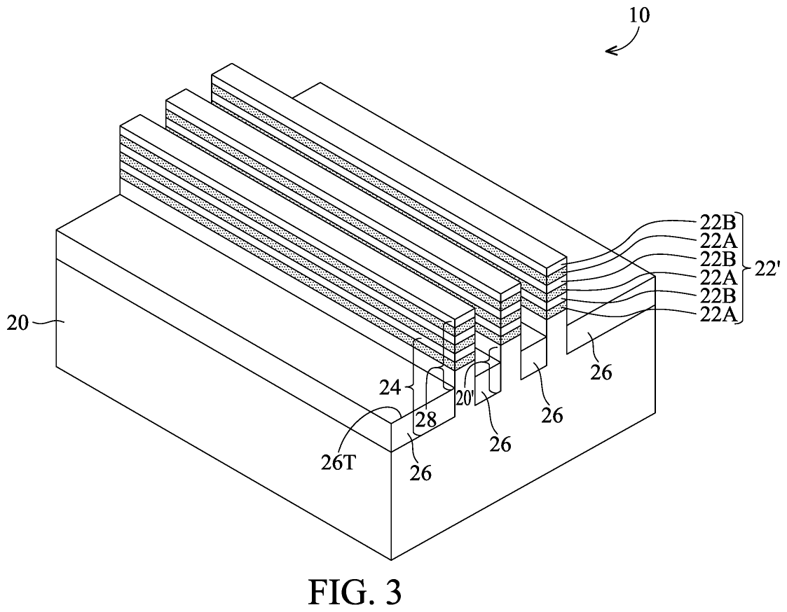

FIG. 3 illustrates the formation of isolation regions 26, which are also referred to as Shallow Trench Isolation (STI) regions throughout the description. The respective process is illustrated as process 206 in the process flow 200 shown in FIG. 26. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

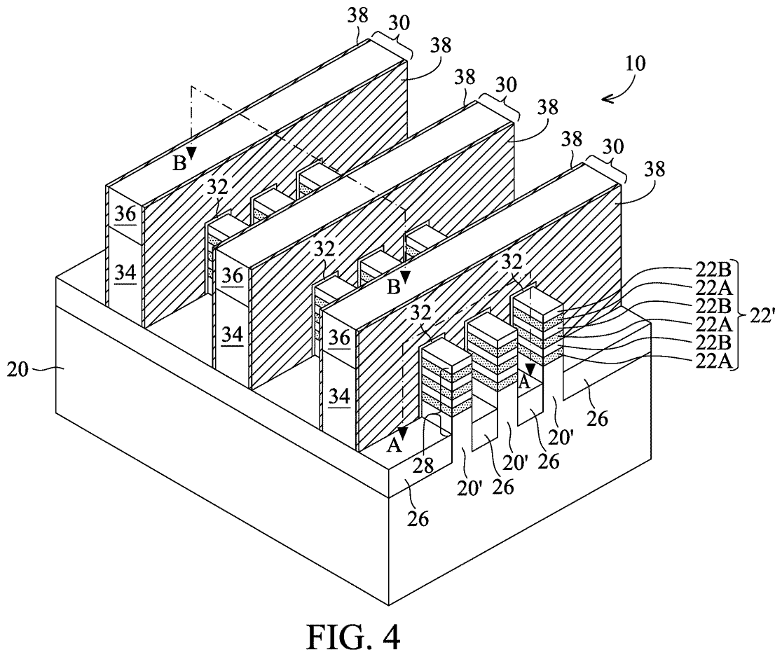

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 26. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a patterning process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

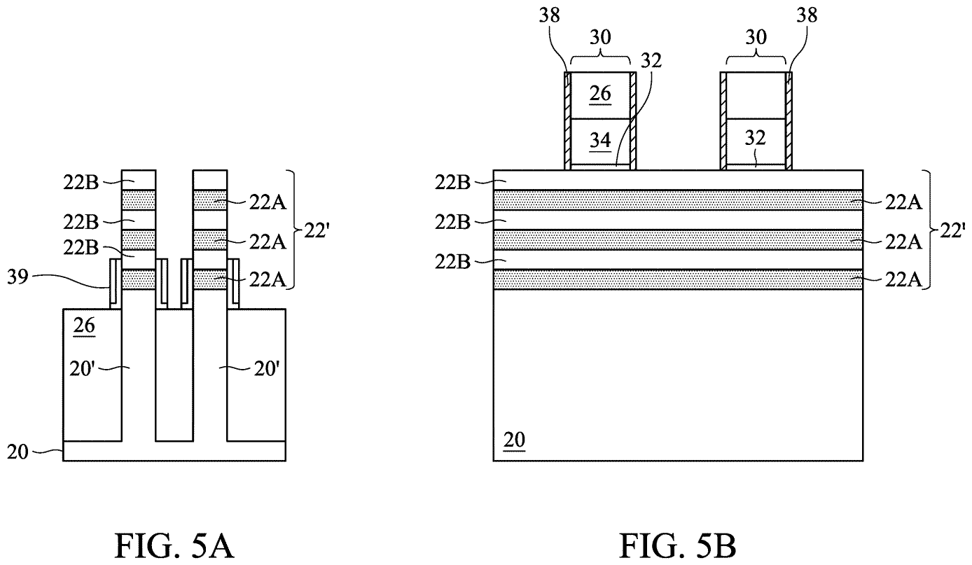

FIGS. 5A and 5B illustrate the cross-sectional views of the structure shown in FIG. 4. FIG. 5A illustrates the reference cross-section A-A in FIG. 4, which cross-section cuts through the portions of protruding fins 28 not covered by gate stacks 30 and gate spacers 38, and is perpendicular to the gate-length direction. Fin spacers 39, which are on the sidewalls of protruding fins 28, are also illustrated. FIG. 5B illustrates the reference cross-section B-B in FIG. 4, which reference cross-section is parallel to the lengthwise directions of protruding fins 28.

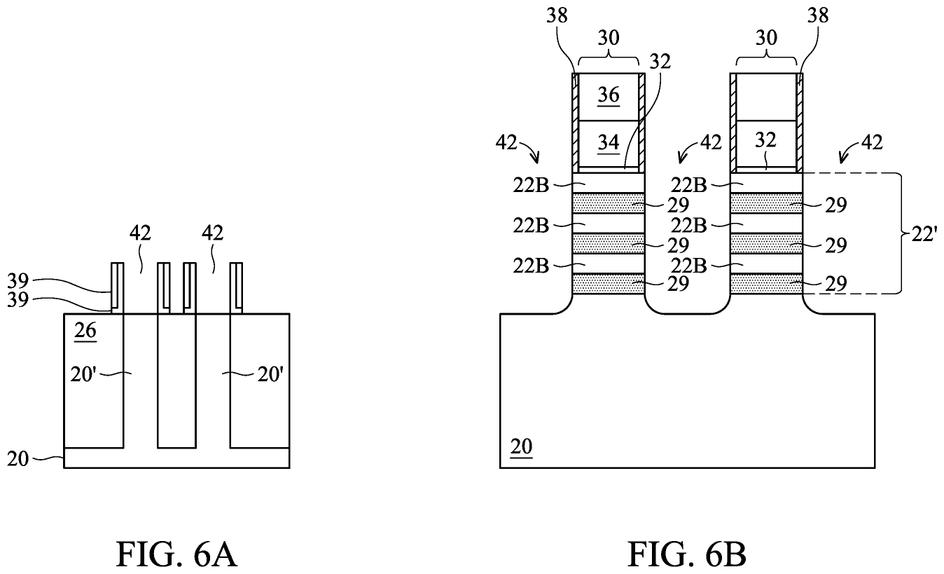

Referring to FIGS. 6A and 6B, a source/drain recessing process is shown. The respective process is illustrated as process 210 in the process flow 200 as shown in FIG. 26. The protruding fins 28 that are not directly underlying dummy gate stacks 30 and gate spacers 38 are etched in an anisotropic etching process. Source/drain recesses 42 are thus formed.

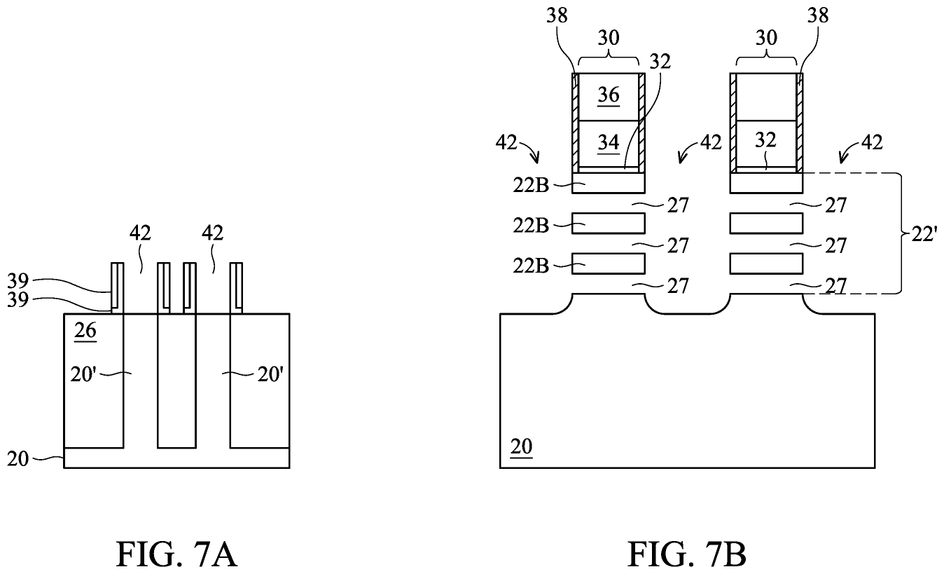

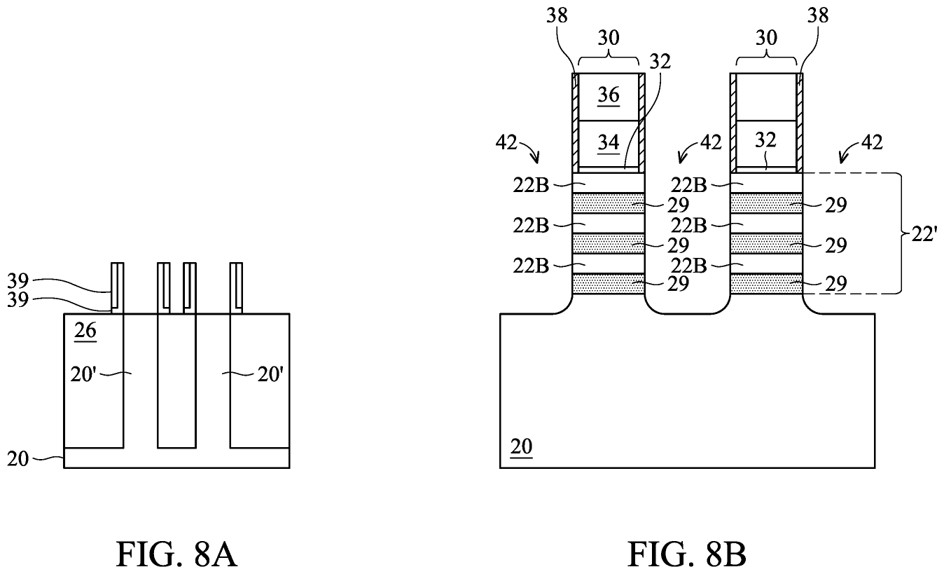

FIGS. 7A, 7B, 8A, and 8B illustrate the replacement of sacrificial layers 22A with disposable interposers 29, which are also used as sacrificial layers in subsequent processes. Referring to FIGS. 7A and 7B, the sacrificial layers 22A are first removed, forming openings 27 between nanostructures 22B. The respective process is illustrated as process 212 in the process flow 200 as shown in FIG. 26.

Referring to FIGS. 8A and 8B, disposable interposers 29 are formed between nanostructures 22B. The respective process is illustrated as process 214 in the process flow 200 as shown in FIG. 26. In accordance with some embodiments, disposable interposers 29 comprise an oxide such as silicon oxide, and thus may also be referred to as Disposable Oxide Interposers (DOIs) 29. In accordance with other embodiments, disposable interposers 29 may comprise other types of dielectric materials such as AlO, SiON, SiC, SiCN, or the like.

The formation of disposable interposers 29 may include depositing a dielectric layer using a conformal deposition process, so that the dielectric layer includes some portions filling openings 27, and some other portions outside of openings 27. A trimming process, which may include an isotropic etching process, or an anisotropic etching process followed by an isotropic etching process, is then performed to etch and remove the portions of the dielectric layer outside of openings 27. The remaining portions of the dielectric layer are thus the disposable interposers 29.

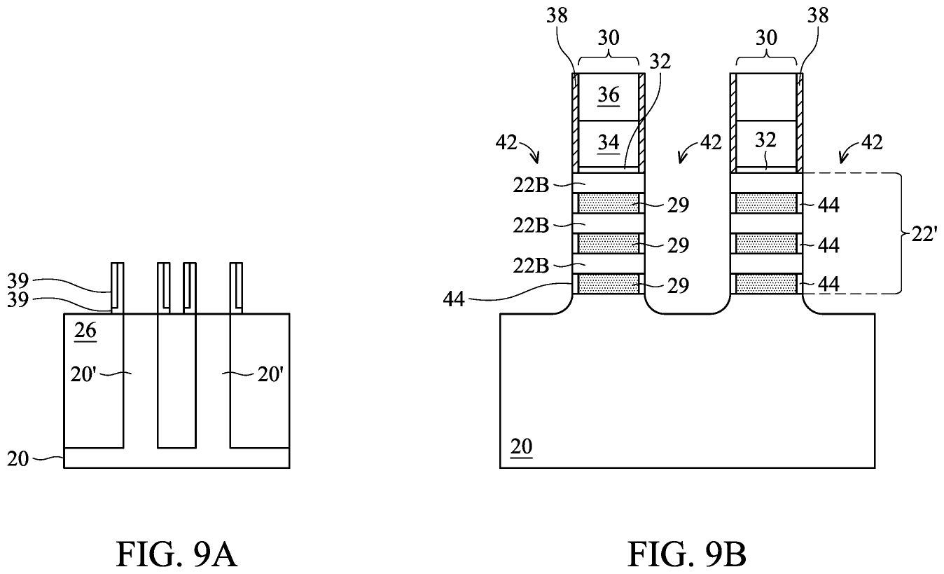

Referring to FIGS. 9A and 9B, disposable interposers 29 are laterally recessed and filled with a dielectric material to form inner spacers 44 (FIG. 9B). The respective process is illustrated as process 216 in the process flow 200 as shown in FIG. 26. The lateral recessing of disposable interposers 29 may be achieved through a wet etching process or a dry etching process. The wet etching process may be performed using a dip process, a spray process, a spin-on process, or the like. Nanostructures 22B are not etched.

After the lateral recessing, inner spacers 44 are formed. In accordance with some embodiments, the formation of inner spacers 44 includes depositing a conformal dielectric layer, which extends into the lateral recesses. Next, an etching process (also referred to as a spacer trimming process) is performed to trim the portions of the dielectric layer outside of the lateral recesses, leaving the portions of the dielectric layer in the lateral recesses. The remaining portions of the dielectric layer are referred to as inner spacers 44.

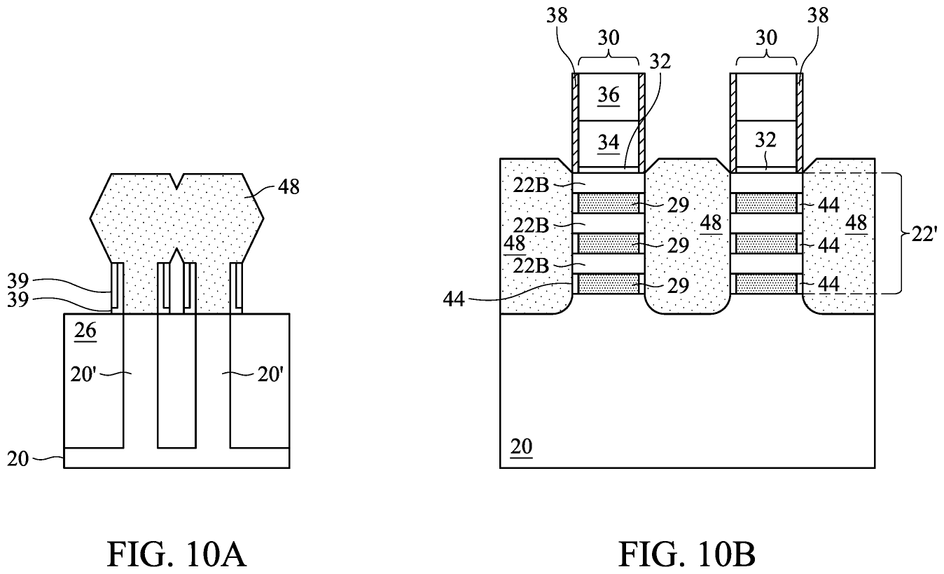

Referring to FIGS. 10A and 10B, epitaxial source/drain regions 48 are formed in recesses 42 through selective epitaxy. The respective process is illustrated as process 218 in the process flow 200 shown in FIG. 26. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown.

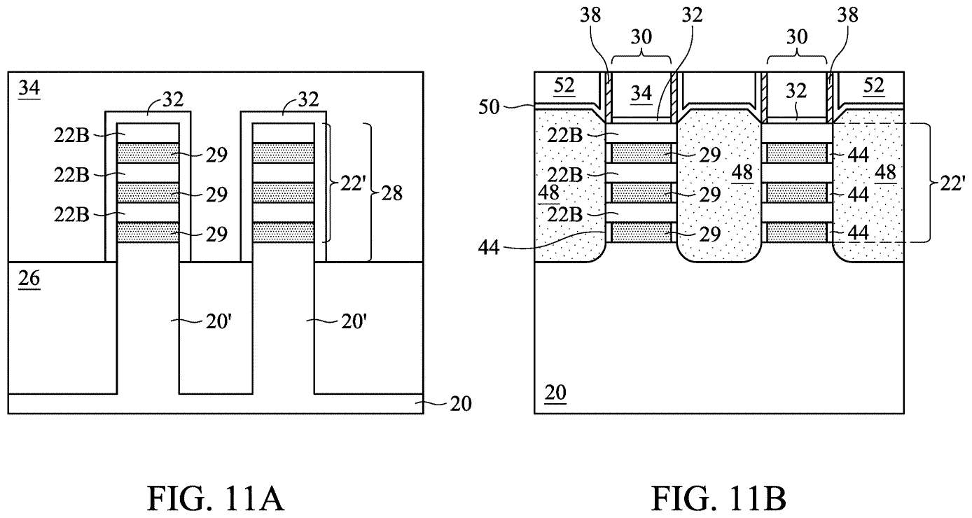

FIGS. 11A and 11B illustrate the cross-sectional views of the structure after the formation of Contact Etch Stop Layer (CESL) 50 and Inter-Layer Dielectric (ILD) 52. The respective process is illustrated as process 220 in the process flow 200 shown in FIG. 26. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIGS. 11A and 11B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

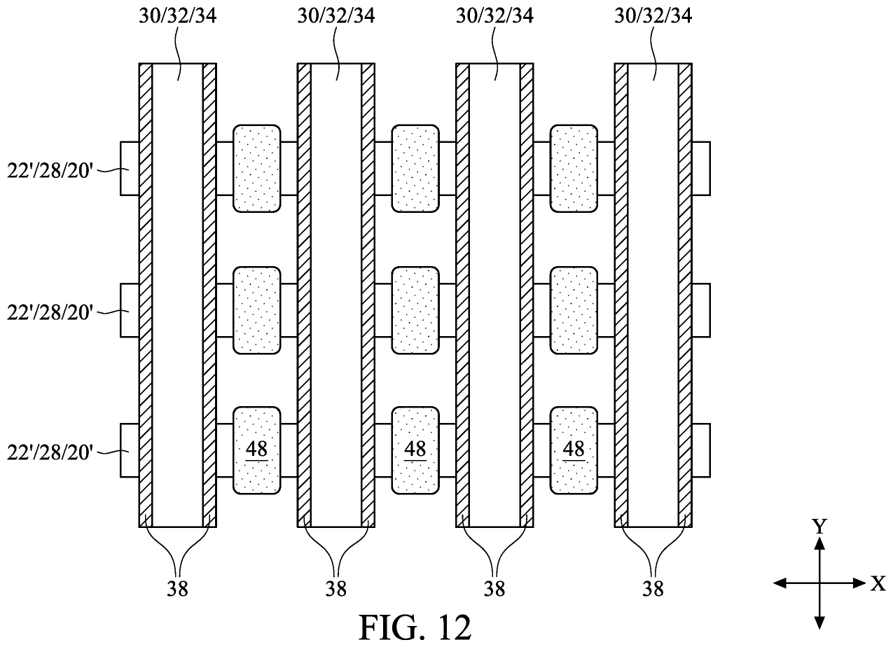

FIG. 12 illustrates a top view of the structure shown in FIGS. 11A and 11B in accordance with some embodiments. Multilayer stacks 22′, substrate strips 20′, and protruding fins 28 (refer to FIG. 11A) have lengthwise directions in the X-direction, and the corresponding cross-sectional view is referred to as the X-cut view. Gate stacks 30, which includes dummy gate electrodes 34 (such as polysilicon strips) have lengthwise directions in the Y-direction, and the corresponding cross-sectional view is referred to as the Y-cut view. Source/drain regions 48 are formed based on some portions of the multilayer stacks 22′ (as viewed in FIG. 11B). The edges of source/drain regions may be in contact with, or may be spaced apart from, gate spacers 38. Although the source/drain regions 48 formed based on different protruding fins 28 are shown as being separated from each other, some of the neighboring source/drain regions 48 may be merged.

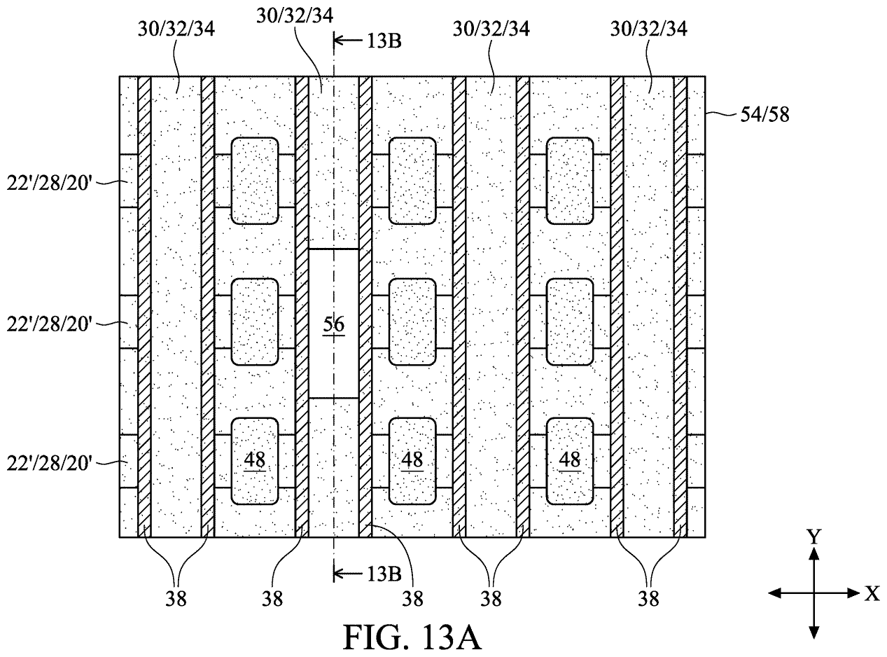

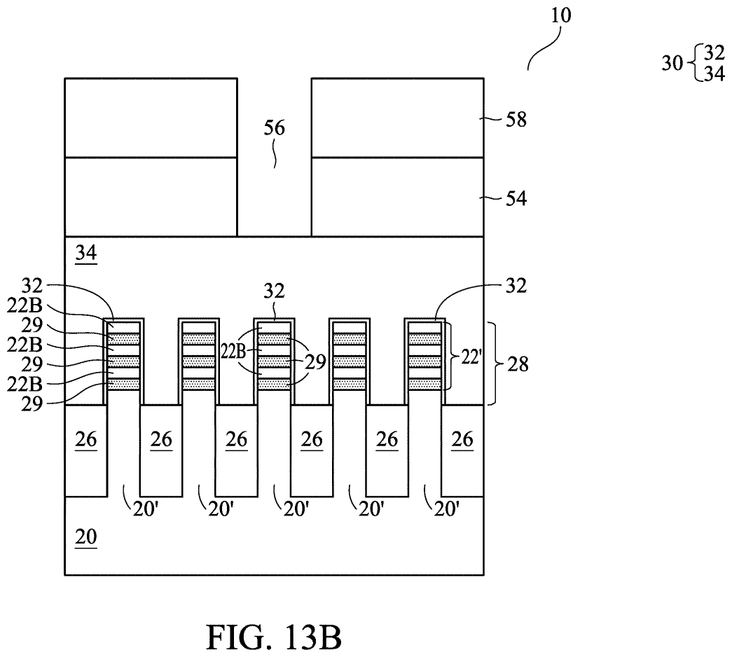

FIGS. 13A and 13B illustrate a top view and a cross-sectional view, respectively, in the formation of hard mask 54 in accordance with some embodiments. FIG. 13B illustrates the cross-section 13B-13B in FIG. 13A. As shown in FIG. 13B, hard mask 54 is formed over dummy gate electrode 34. Hard mask 54 may comprise a material(s) such as SiN, silicon (for example, amorphous silicon), TiN, BN, or the like, or multilayers thereof. Etching mask 58, which is patterned, is formed over hard mask 54. In accordance with some embodiments, etching mask 58 comprises photoresist, and may have a single layer structure, a tri-layer structure, or the like. Etching mask 58 is patterned.

Hard mask 54 is etched using etching mask 58 to define patterns and to form opening 56, through which dummy gate electrode 34 is exposed. As shown in FIG. 13A, which is a top view, opening 56 may be elongated, and is directly over one of dummy gate electrode 34. Furthermore, opening 56 is over and crosses one or more multilayer stack 22′. Opening 56 may have its longer edges aligned to the interface between dummy gate stack 30 and gate spacers 38, or may overlap gate spacers 38, and may or may not overlap CESL 50 and ILD 52. Etching mask 58 may (or may not) be removed after the patterning of hard mask 54.

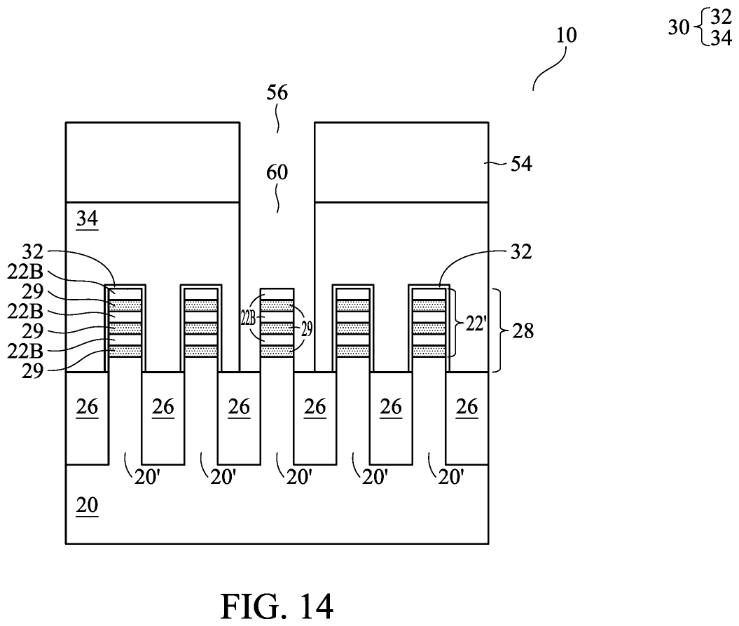

Hard mask 54 is then used to etch the underlying dummy gate electrode 34, until dummy gate dielectric 32 is exposed. Dummy gate dielectric 32 is then removed, for example, through an isotropic etching process, so that multilayer stacks 22′ are revealed. The resulting structure is shown in FIG. 14. The respective process is illustrated as process 222 in the process flow 200 shown in FIG. 26. Trench 60 is thus formed in dummy gate electrode 34. The etching may be anisotropic, so that the edges of the dummy gate electrode 34 facing trench 60 are vertical and straight.

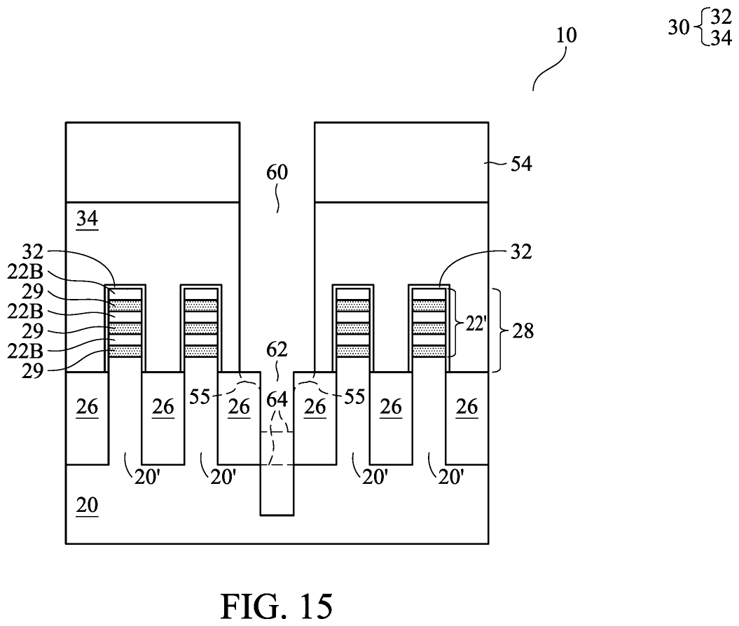

Next, an etching process(es) is performed to remove the exposed multilayer stack 22′, followed by the further etching of the underlying semiconductor material such as semiconductor strips 20′. The respective process is illustrated as process 224 in the process flow 200 shown in FIG. 26. Trench 62 is thus formed between neighboring STI regions 26, as shown in FIG. 15. In accordance with some embodiments, trench 62 extends to a level lower than the bottom surfaces of STI regions 26, as shown in FIG. 15. In accordance with alternative embodiments, the bottom of trench 62 may also be level with or higher than the bottom surfaces of STI regions 26, as shown by dashed lines 64.

It is appreciated that in the removal of multilayer stack 22′, STI regions 26 may suffer from loss. For example, the etching of disposable interposers 29 in the multilayer stack 22′ may cause the loss of STI regions 26 due to the similarity of the materials of STI regions 26 and multilayer stack 22′, which results in the low etching selectivity between STI regions 26 and multilayer stack 22′. Accordingly, the exposed portions of STI regions 26 may be recessed. Dashed lines 55 schematically illustrate the correspond profile of STI regions 26 caused by the loss.

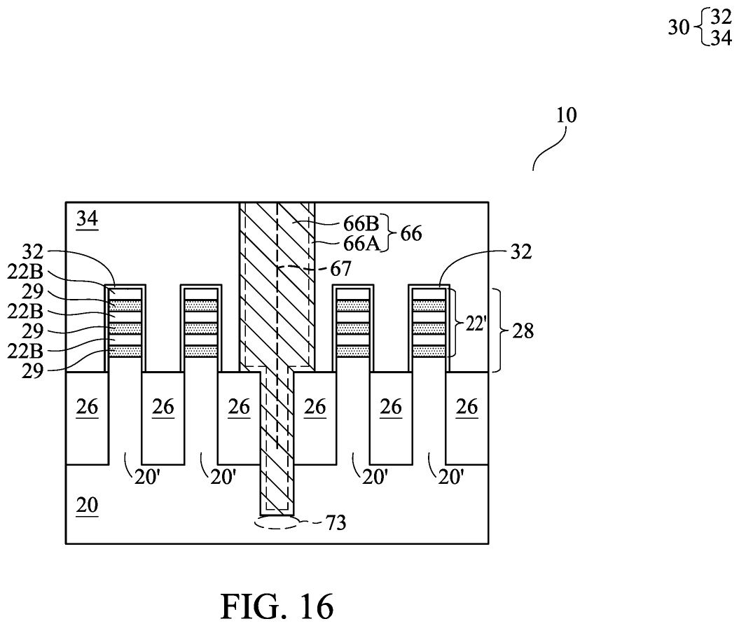

FIG. 16 illustrates the filling of trenches 60 and 62 to form CPODE isolation region 66. The respective process is illustrated as process 226 in the process flow 200 shown in FIG. 26. In accordance with some embodiments, the filling process may include depositing one or more dielectric material to fully fill trenches 60 and 62. A planarization process such as a CMP process or a mechanical grinding process may then be performed to remove excess portions of the dielectric material over dummy gate electrode 34, thus forming CPODE isolation region 66.

In accordance with some embodiments, the material of CPODE isolation region 66 may be selected from dielectric materials that have a relatively high etching selectivity in the subsequent removal of disposable interposers 29. For example, the CPODE isolation region 66 may be selected from SiN, SiON, SiOCN, SiCN, or the like, or combinations thereof. In accordance with some embodiments, CPODE isolation region 66 has a single-layer structure, with the entire CPODE isolation region 66 being formed of a homogeneous dielectric material such as SiN.

In accordance with alternative embodiments, CPODE isolation region 66 may have a multilayer structure including a dielectric liner 66A, and a dielectric filling region 66B over the dielectric liner 66A. Both of the dielectric filling region 66B and dielectric liner 66A may also have a high etching selectivity relative to that of the disposable interposers 29, so that when the disposable interposers 29 is etched, CPODE isolation region 66 is also not etched.

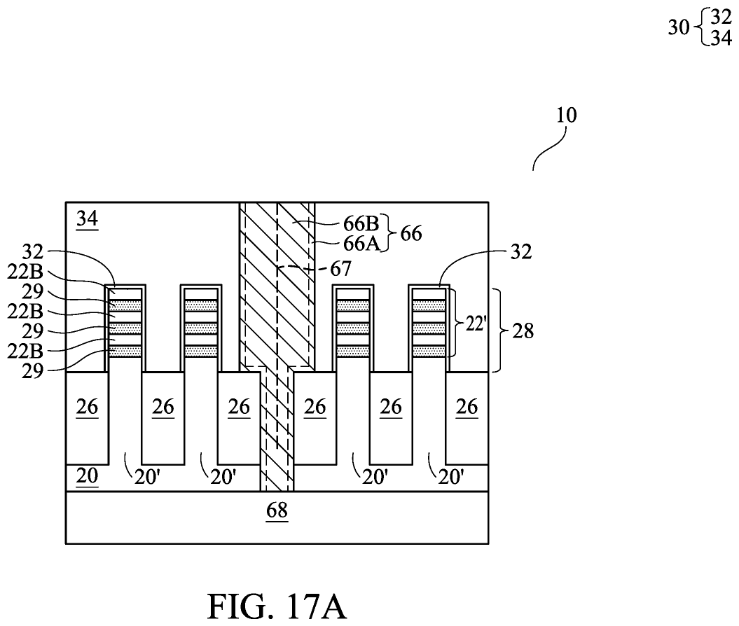

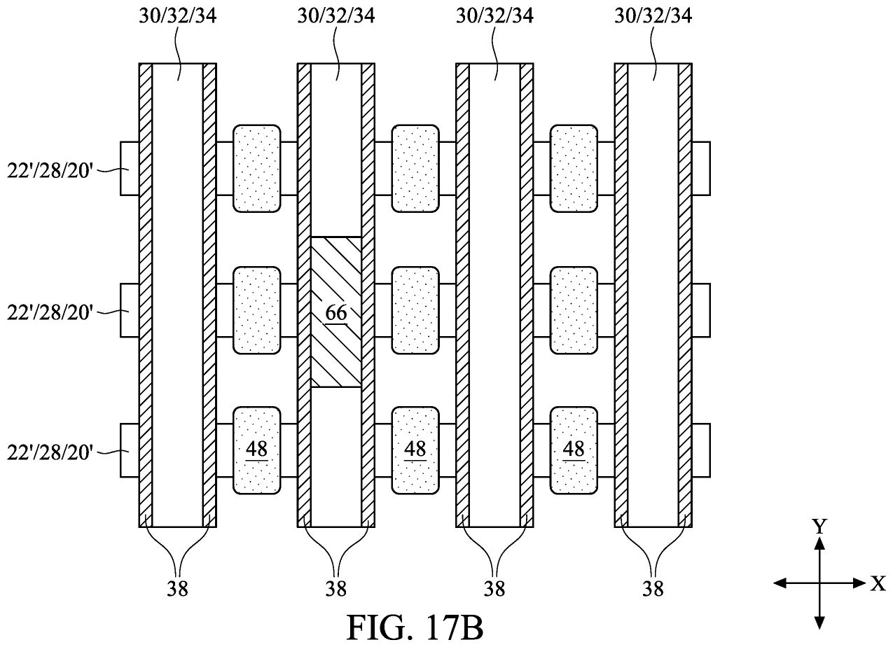

In a subsequent process, a backside grinding process is performed from the backside of wafer 10. The respective process is illustrated as process 228 in the process flow 200 shown in FIG. 26. Semiconductor substrate 20 is thinned. The backside grinding process is performed until the CPODE isolation region 66 is exposed to the backside of wafer 10. In accordance with some embodiments, as shown in FIG. 17A, after the backside grinding process, a portion of the bulk semiconductor substrate 20 may be left under STI regions 26. When CPODE isolation region 66 comprises dielectric liner 66A, the bottom portion of the dielectric liner 66A may be removed, exposing dielectric filling region 66B to the backside of wafer 10.

Next, as also shown in FIG. 17A, a backside dielectric layer 68 is formed through a deposition process. The respective process is illustrated as process 230 in the process flow 200 shown in FIG. 26. In accordance with some embodiments, backside dielectric layer 68 is formed of or comprises an oxide, a nitride, or the like. For example, backside dielectric layer 68 may comprise silicon oxide, silicon nitride, silicon oxynitride, silicon oxycarbide, silicon carbide, silicon oxy-carbo-nitride, or the like.

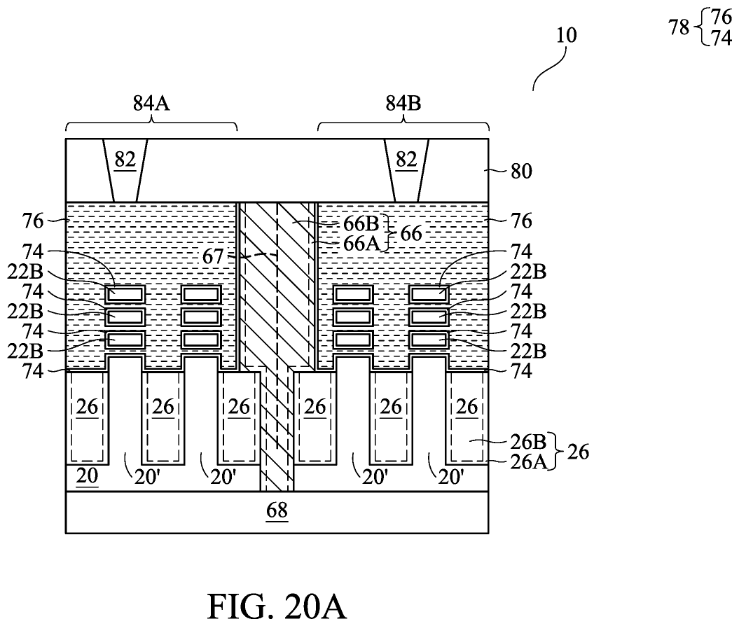

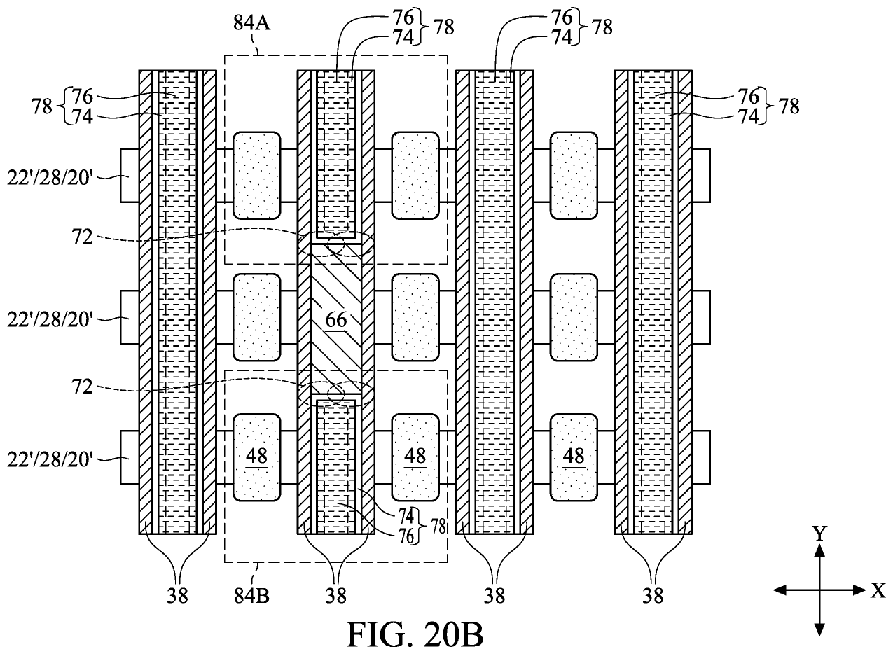

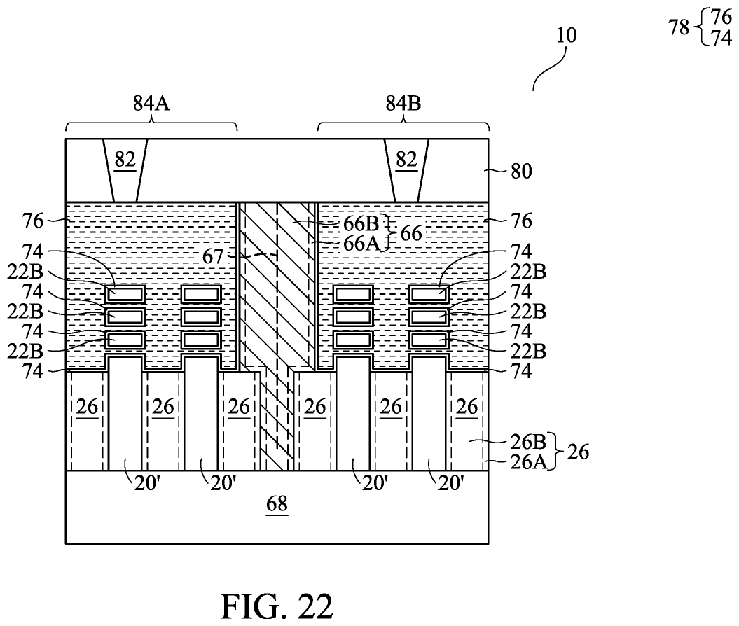

In accordance with some embodiments, at a time the final structure as shown in FIGS. 20A and 20B (or in the final structure as shown in FIG. 22) is formed, backside dielectric layer 68 may still be a blank layer without comprising other materials/features (such as conductive features) therein. Backside dielectric layer 68 is also referred to as an insulator substrate.

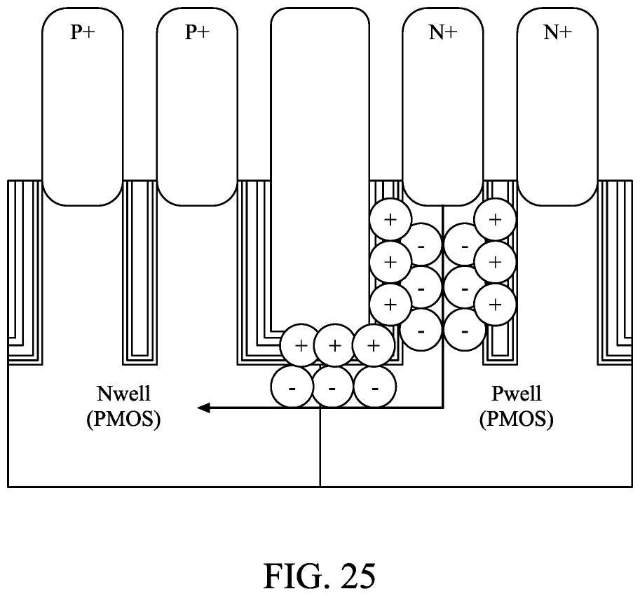

It is appreciated that CPODE isolation region 66, when formed of silicon nitride, may attract charges in the semiconductor substrate 20 due to the high defect density in the silicon nitride. This may cause a leakage path in region 73 (FIG. 16). For example, FIG. 25 illustrates two neighboring semiconductor fins formed over a P-well region (for forming an NMOS) and a N-well region (for forming a PMOS). An STI region is formed in the P-well region and the N-well region. It is appreciated that the STI region may comprise a nitride liner contacting the P-well region and the N-well region. Silicon nitride has a high density of defects, and may trap charges, which may accumulate to form a leakage path. The leakage path in the nitride liner is shown by the positive charges. Also, negative charges are attracted by the accumulated positive charges to form a leakage path.

By removing the portion of the semiconductor substrate that may form the leakage path, and by forming a backside dielectric layer 68 for the CPODE isolation region 66 to land thereon, the leakage path is eliminated.

FIG. 17B illustrates a top view of the structure shown in FIG. 17A, wherein CPODE isolation region 66 is illustrated.

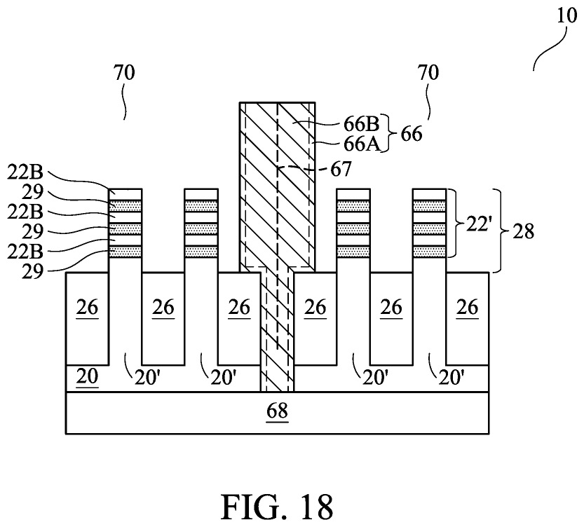

Next, dummy gate electrodes 34 and dummy gate dielectrics 32 (and hard masks 36, if remaining) are removed in one or more etching processes, so that recesses 70 are formed, as shown in FIG. 18. The respective process is illustrated as process 232 in the process flow 200 shown in FIG. 26. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 70 exposes and/or overlies portions of multilayer stacks 22′, which include the future channel regions in subsequently completed transistors.

The dummy gate electrodes 34 and dummy gate dielectrics 32 may also have a high etching selectivity to CPODE isolation region 66, so that in the etching of dummy gate electrodes 34 and dummy gate dielectrics 32, CPODE isolation region 66 is not etched.

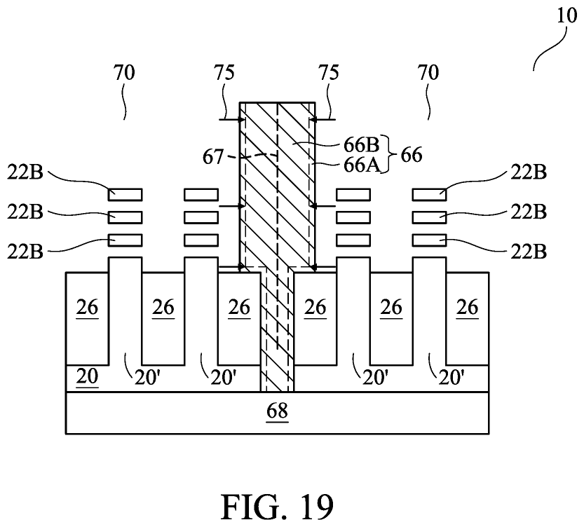

Disposable interposers 29 are then removed to extend recesses 70 between nanostructures 22B. The respective process is illustrated as process 234 in the process flow 200 shown in FIG. 26. The resulting structure is shown in FIG. 19. Disposable interposers 29 may be removed by performing an isotropic etching process such as a wet etching process using an etchant that are selective to the materials of disposable interposers 29, while nanostructures 22B and substrate 20 remain relatively un-etched as compared to disposable interposers 29. STI regions 26 may be slightly recessed or may not be recessed. For example, a silicon nitride cap layer may be formed (in the step shown in FIG. 3) on each of STI regions 26 to protect STI regions 26.

In accordance with some embodiments in which disposable interposers 29 are formed of silicon oxide (DOI), when dry etching is performed, the etching gases may include the mixture of NF₃ and NH₃, the mixture of HF and NH₃, or the like. When wet etching is performed, diluted HF may be used.

In the etching of disposable interposers 29, due to the selection of the material(s) of CPODE isolation region 66 to have a high etching selectivity relative to disposable interposers 29, CPODE isolation region 66 is not etched. For example, the etching selectivity ER29/ER66 may be greater than about 5, greater than about 10, 20, 50, or higher, with ER29 being the etching rate of disposable interposers 29, and ER66 being the etching rate of CPODE isolation region 66. Accordingly, in the etching of disposable interposers 29, the lateral etching of CPODE isolation region 66, as represented by arrows 75 in FIG. 19, is avoided. For example, when CPODE isolation region 66 comprises silicon nitride, while disposable interposers 29 comprise silicon oxide, CPODE isolation region 66 will not be damaged.

In accordance with some embodiments, seam 67 is formed in CPODE isolation region 66. In accordance with alternative embodiments, there is no seam formed.

Referring to FIG. 20B, regions 72 are marked. Regions 72 are the regions in which CPODE isolation region 66 may be adversely removed if CPODE isolation region 66 includes a material (such as a silicon oxide liner) that has a low etching selectivity relative to the material of disposable interposers 29 (such as silicon oxide also). When these portions of the silicon oxide liner are removed, the subsequently formed metal gate will be located closer to the respective source/drain contact plugs, and issues such as electrical shorting or leakage may occur. Furthermore, the bottom portion of the silicon oxide liner may be encroached, making it difficult to form a conformal replacement gate dielectric, again may causing electrical shorting or leakage.

In accordance with the embodiments of the present disclosure, by increasing the etching selectivity ER29/ER66, the illustrated regions 72 in FIG. 20B will have reduced damages, or may be free from damages.

Referring to FIGS. 20A and 20B, gate dielectrics 74 and gate electrodes 76 are formed, hence forming replacement gate stacks 78. The respective process is illustrated as process 236 in the process flow 200 shown in FIG. 26. In accordance with some embodiments, each of gate dielectrics 74 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 76 are also formed. In the formation process, conductive layers are first formed on the high-k dielectric layer, and the remaining portions of recesses 70 are fully filled. Gate electrodes 76 may include a metal-containing material such as TiN, TaN, TiAl, TiAlC, cobalt, ruthenium, aluminum, tungsten, combinations thereof, and/or multilayers thereof. For example, gate electrodes 76 may comprise any number of layers, any number of work function layers, and possibly a filling material. The replacement gate stacks 78 also fill the spaces between adjacent ones of nanostructures 22B, and fill the spaces between the bottom ones of nanostructures 22B and the underlying substrate strips 20′.

After the filling of recesses 70, a planarization process such as a CMP process or a mechanical grinding process is performed to remove the excess portions of the gate dielectrics 74 and gate electrodes 76, which excess portions are over the top surface of ILD 52 (FIG. 11B). Gate electrodes 76 and gate dielectrics 74 are collectively referred to as gate stacks 78 of the resulting transistors.

FIG. 20A further illustrates the formation of dielectric layer(s) 80 and gate contact plugs 82 in accordance with some embodiments. Dielectric layers 80 may include an inter-layer dielectric, and may or may not include an etch stop layer between the inter-layer dielectric and the replacement gate stacks 78. Gate contact plugs 82 are electrically connected to gate electrodes 76. GAA transistors 84A and 84B are thus formed.

Although the structure of the GAA transistors 84A and 84B in another cross-section, which is perpendicular to the cross-section of FIG. 20A, is not shown. The structure in the other cross-section may be realized from FIG. 11B, except that the dummy gate stacks 30 in FIG. 11B are replaced with the replacement gate stacks 78.

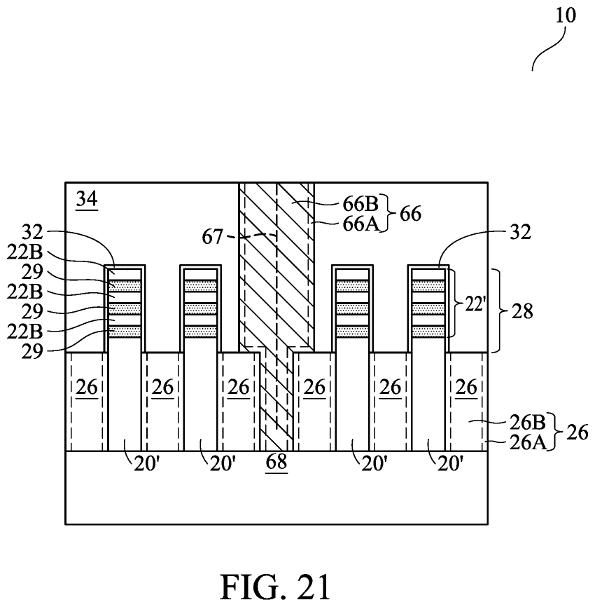

FIGS. 21 and 22 illustrate the views of intermediate stages in the formation of a structure in accordance with alternative embodiments. These embodiments are essentially the same as that shown in the preceding embodiments, except that in the backside grinding process, the bulk semiconductor substrate 20 is removed, and STI regions 26 are exposed from bottom. In accordance with these embodiments, the backside dielectric layer 68 may also be a blank layer without other materials/features (such as conductive features) therein in the final structure as shown in FIG. 22, which is the structure after the respective replacement gate stack 78 is formed.

It is appreciated that STI regions 26 may include a dielectric liner 26A and dielectric filling region 26B that are distinguishable from each other. For example, dielectric liner 26A and dielectric filling region 26B may be formed of the same material but have different properties such as different densities. Dielectric liner 26A and dielectric filling region 26B may also be formed of different materials. For example, dielectric liner 26A may be formed of silicon oxide, and dielectric filling region 26B may be formed of silicon nitride.

In accordance with alternative embodiments, dielectric liner 26A may be formed of silicon nitride, and dielectric filling region 26B may be formed of silicon oxide. In the backside grinding process, the bottom portions of the dielectric liners 26A is removed, and thus the dielectric filling regions 26B are in physical contact with the backside dielectric layer 68 in accordance with these embodiments. As a comparison, in the structure shown in FIG. 20A, the bottom portions of dielectric liners 26A may still exist in the final structure.

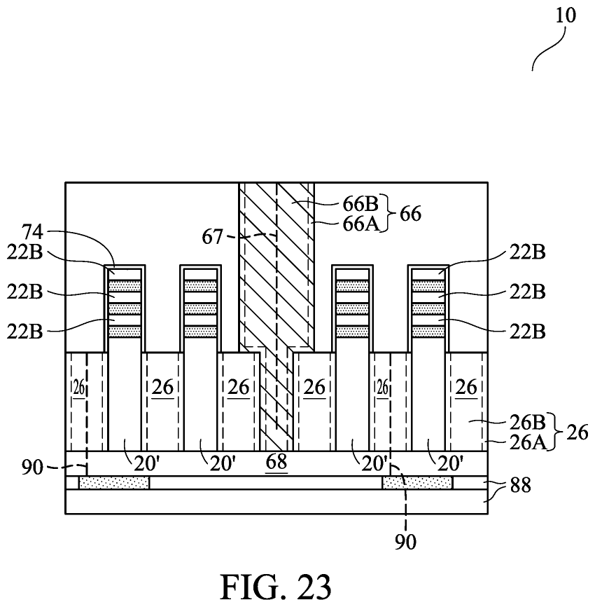

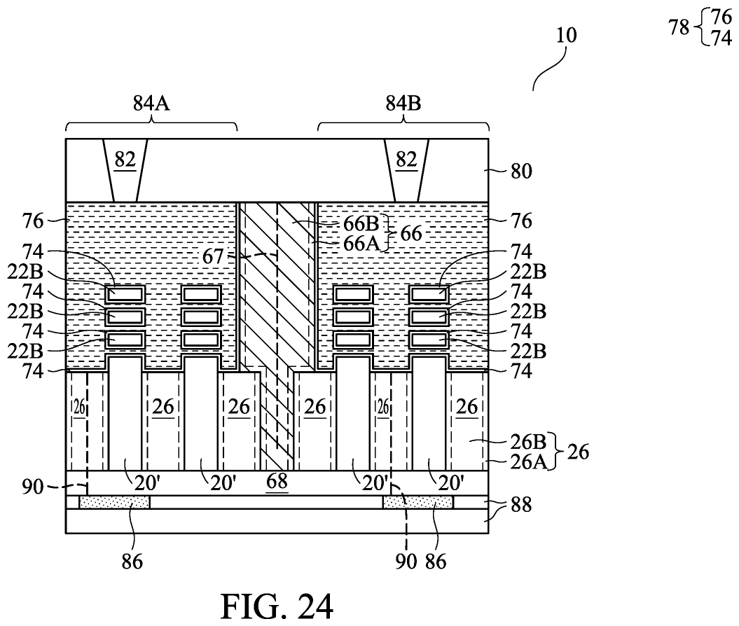

FIGS. 23 and 24 illustrate the views of intermediate stages in the formation of a structure in accordance with alternative embodiments. These embodiments are essentially the same as that shown in the preceding embodiments, except that a backside routing structure is formed. For example, dielectric layers 88 are formed, and backside metal lines 86 are formed in dielectric layers 88.

The backside metal lines 86 may be electrically connected to the front side features through conductive features 90, which may penetrate through the STI regions 26. The conductive features 90 are schematically illustrated using dashed lines. The backside metal lines 86 may be used for conducting power and/or signals. Accordingly, the structure in accordance with the embodiments of the present disclosure is also compatible with the formation of backside routing.

The embodiments of the present disclosure have some advantageous features. With the CPODE isolation regions adopting a dielectric material (such as silicon nitride) that is different from the material of the sacrificial layers in multilayer stacks, the damage to the CPODE isolation region in the etching of the sacrificial layers is eliminated. Silicon nitride, however, may result in a leakage path to be generated in a portion of the semiconductor substrate underlying and contacting the CPODE isolation region. By removing the underlying portion of the semiconductor substrate and replacing with a dielectric layer, the leakage path is further removed.

In accordance with some embodiments of the present disclosure, a method comprises forming a dummy gate stack on a first protruding structure of a wafer, wherein the first protruding structure comprises a first semiconductor layer; etching the dummy gate stack to form a trench in the dummy gate stack and to reveal the first semiconductor layer; removing the first semiconductor layer and a semiconductor strip underlying the first semiconductor layer to extend the trench downwardly; filling the trench with a dielectric material to form a dielectric isolation region; performing a backside grinding process on a semiconductor substrate of the wafer, wherein the dielectric isolation region is revealed from a backside of the wafer; and forming a backside dielectric layer on the backside of the wafer, wherein the backside dielectric layer contacts the dielectric isolation region.

In an embodiment, an entirety of the dielectric isolation region is formed of a homogeneous dielectric material. In an embodiment, the dummy gate stack is further over a second protruding structure comprising a second semiconductor layer; and a sacrificial layer underlying and contacting the second semiconductor layer, wherein the method further comprises, after the dielectric isolation region is formed, etching the sacrificial layer using an etching chemical to generate a space, wherein the dielectric isolation region is exposed to the etching chemical, and the sacrificial layer and the dielectric isolation region comprise different dielectric materials; and forming a replacement gate stack comprising a portion in the space.

In an embodiment, the dielectric isolation region is not etched by the etching chemical. In an embodiment, the sacrificial layer comprises silicon oxide, and the dielectric isolation region comprises silicon nitride. In an embodiment, the replacement gate stack encircles the second semiconductor layer. In an embodiment, when the sacrificial layer is etched, a sidewall of the dielectric isolation region is exposed to the etching chemical. In an embodiment, after the backside grinding process, a portion of the semiconductor substrate is left to separate the portion of the semiconductor substrate from the backside dielectric layer.

In an embodiment, the dielectric isolation region is between opposing shallow trench isolation regions, and wherein during the backside grinding process, the opposing shallow trench isolation regions are polished. In an embodiment, the method further comprises forming metal lines on the backside of the wafer, wherein the metal lines are in contact with the backside dielectric layer.

In accordance with some embodiments of the present disclosure, a structure comprises a first plurality of semiconductor nanostructures, wherein upper ones of the first plurality of semiconductor nanostructures overlap respective lower ones of the first plurality of semiconductor nanostructures; a first gate stack on the first plurality of semiconductor nanostructures; a second plurality of semiconductor nanostructures, wherein upper ones of the second plurality of semiconductor nanostructures overlap respective lower ones of the second plurality of semiconductor nanostructures; a second gate stack on the second plurality of semiconductor nanostructures; a first shallow trench isolation region and a second shallow trench isolation region lower than the first plurality of semiconductor nanostructures and the second plurality of semiconductor nanostructures; a dielectric isolation region between and contacting the first gate stack and the second gate stack, and between and contacting the first shallow trench isolation region and the second shallow trench isolation region; and a backside dielectric layer underlying and contacting the dielectric isolation region.

In an embodiment, an entirety of the dielectric isolation region is formed of a homogeneous dielectric material. In an embodiment, the entirety of the dielectric isolation region is formed of silicon nitride. In an embodiment, the structure further comprises a semiconductor substrate underlying the first shallow trench isolation region and the second shallow trench isolation region, wherein the semiconductor substrate is over and contacting the backside dielectric layer. In an embodiment, the structure further comprises a backside metal line underlying and contacting the backside dielectric layer. In an embodiment, the first gate stack comprises a gate dielectric, and wherein a vertical portion of the gate dielectric contacts the dielectric isolation region to form a vertical interface.

In accordance with some embodiments of the present disclosure, a structure comprises a first transistor comprising a first gate stack; a second transistor comprising a second gate stack, wherein in a top view of the structure, lengthwise directions of the first gate stack and the second gate stack are aligned to a same straight line; a first shallow trench isolation region overlapped by the first gate stack; a second shallow trench isolation region overlapped by the second gate stack; a dielectric isolation region comprising an upper portion separating the first gate stack from the second gate stack; and a lower portion separating the first shallow trench isolation region from the second shallow trench isolation region, wherein an entirety of the dielectric isolation region is formed of a homogeneous dielectric material; and a backside dielectric layer underlying and contacting the lower portion of the dielectric isolation region.

In an embodiment, the entirety of the dielectric isolation region comprises silicon nitride. In an embodiment, the backside dielectric layer comprises silicon nitride. In an embodiment, the backside dielectric layer comprises silicon oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack over a first semiconductor channel and a second semiconductor channel;
etching the gate stack to form a trench between the first semiconductor channel and the second semiconductor channel, wherein the trench penetrates through shallow trench isolation regions underlying the gate stack, and wherein the trench extends to a top surface of a bulk semiconductor substrate;
filling the trench with a dielectric material to form a dielectric isolation region;
performing a backside grinding process on the bulk semiconductor substrate until a back surface of the dielectric isolation region is revealed; and
forming a backside dielectric layer contacting the back surface of the dielectric isolation region.

2. The method of claim 1, wherein the dielectric isolation region is formed of a homogeneous dielectric material.

3. The method of claim 1, wherein the gate stack is a dummy gate stack, and the method further comprises:
removing the dummy gate stack to reveal sidewalls of the dielectric isolation region; and
etching a disposable interposer underlying the first semiconductor channel to leave a space, wherein when the disposable interposer is etched, the dielectric isolation region is exposed to a respective etching chemical, and is unetched.

4. The method of claim 3 further comprising forming a replacement gate stack comprising a portion in the space.

5. The method of claim 4, wherein the replacement gate stack encircles the first semiconductor channel.

6. The method of claim 3, wherein the disposable interposer is formed of a different dielectric material than the dielectric isolation region.

7. The method of claim 1, wherein after the backside grinding process, a portion of the bulk semiconductor substrate is left.

8. The method of claim 1, wherein the dielectric isolation region is between two of the shallow trench isolation regions, and wherein during the backside grinding process, the shallow trench isolation regions are polished.

9. The method of claim 1 further comprising forming metal lines on an opposite side of the backside dielectric layer than the dielectric isolation region.

10. A method comprising:
forming a multilayer stack comprising a sacrificial layer and a semiconductor nanostructure over the sacrificial layer;
forming a dummy gate stack over the multilayer stack;
replacing the sacrificial layer with a disposable interposer;
forming a dielectric isolation region in the dummy gate stack;
performing a backside grinding process on a bulk semiconductor substrate until a back surface of the dielectric isolation region is exposed;
forming a backside dielectric layer contacting the back surface of the dielectric isolation region;
removing the dummy gate stack to form a recess, wherein a sidewall of the disposable interposer are exposed to the recess;
etching the disposable interposer through the recess, wherein when the disposable interposer is etched, the dielectric isolation region is exposed to an etching chemical used for etching the disposable interposer, wherein a first etching rate of the dielectric isolation region is lower than a second etching rate of the disposable interposer; and
forming a replacement gate stack in the recess.

11. The method of claim 10, wherein the dielectric isolation region is formed of a homogenous dielectric material.

12. The method of claim 10, wherein the dielectric isolation region has a multilayer structure.

13. The method of claim 10, wherein the dielectric isolation region comprises silicon nitride, and the backside dielectric layer comprises silicon oxide.

14. The method of claim 10, wherein after the backside grinding process, a layer of the bulk semiconductor substrate is left, and has a first bottom surface coplanar with a second bottom surface of the dielectric isolation region.

15. The method of claim 10 further comprising forming a backside metal line underlying and contacting the backside dielectric layer.

16. The method of claim 10, wherein the replacement gate stack comprises a gate dielectric, and wherein a vertical portion of the gate dielectric contacts the dielectric isolation region to form a vertical interface.

17. A method comprising:
forming a structure comprising:
a multilayer stack comprising a disposable interposer and a semiconductor nanostructure over the disposable interposer; and
a dummy gate stack over the multilayer stack;
forming a dielectric isolation region in the dummy gate stack;
removing the dummy gate stack to expose a sidewall of the dielectric isolation region;
etching the disposable interposer using an etching chemical, wherein the sidewall of the dielectric isolation region is exposed to the etching chemical; and
forming a replacement gate stack in a recess left by the dummy gate stack and the disposable interposer.

18. The method of claim 17, wherein when the disposable interposer is etched, the dielectric isolation region has a lower etching rate than the disposable interposer.

19. The method of claim 17 further comprising:
performing a backside grinding process until a back surface of the dielectric isolation region is exposed; and
forming a backside dielectric layer contacting the back surface of the dielectric isolation region.

20. The method of claim 19 further comprising forming a via that is over and electrically connected to the replacement gate stack, wherein at a time after the via is formed, the backside dielectric layer is a blanket layer free from conductive features therein.
